(19) United States
(12) Patent Application Publication
(10) Pub. No.: US 2006/0141376 A1
(43) Pub. Date: Jun. 29, 2006

(54) Methods and systems for controlling variation in dimensions of patterned features across a wafer

(76) Inventors: Ady Levy, Sunnyvale, CA (US); Michael Hanna, San Jose, CA (US); Dan Wack, Los Altos, CA (US); John Fielden, Los Altos, CA (US); Christopher F. Bevis, Los Gatos, CA (US); Larry Wagner, San Jose, CA (US)

Correspondence Address: DAFFER MCDANIEL, LLP, P.O. BOX 684908, AUSTIN, TX, 78768, US

(21) Appl. No.: 11/314,638

(22) Filed: Dec. 20, 2005

Related U.S. Application Data
(60) Provisional application No. 60/638,857, filed on Dec. 22, 2004.

(51) Int. Cl. G06F 17/50; H01L 21/66; G03C 5/00; G01C 25/00

(52) U.S. Cl. 430/30; 438/14; 702/97; 716/4

(57) ABSTRACT

Methods and systems for controlling variation in dimensions of patterned features across a wafer are provided. One method includes measuring a characteristic of a latent image formed in a resist at more than one location across a wafer during a lithography process. The method also includes altering a parameter of the lithography process in response to the characteristic to reduce variation in dimensions of patterned features formed across the wafer by the lithography process. Altering the parameter compensates for non-time varying spatial variation in a temperature to which the wafer is exposed during a post exposure bake step of the lithography process and an additional variation in the post exposure bake step.

### PRIORITY CLAIM

This application claims priority to U.S. Provisional Application No. 60/638,857 entitled “Methods and Systems for Controlling the Repeatability and Uniformity of Lithographic Pattern Dimensions,” filed Dec. 22, 2004 which is incorporated by reference as if fully set forth herein.

### BACKGROUND OF THE INVENTION

1. Field of the Invention

This invention generally relates to methods and systems for controlling variation in dimensions of patterned features across a wafer. Certain embodiments relate to altering a parameter of a lithography process in response to a characteristic of a latent image measured at more than one location across a wafer to reduce variation in dimensions of patterned features formed across the wafer by the lithography process.

2. Description of the Related Art

The following description and examples are not admitted to be prior art by virtue of their inclusion in this section.

Semiconductor fabrication processes involve a number of lithography steps to form various features and multiple levels of a semiconductor device. Lithography involves transferring a pattern to a resist formed on a semiconductor substrate, which may be commonly referred to as a wafer. A reticle, or a mask, is disposed above the resist and typically has substantially transparent regions and substantially opaque regions configured in a pattern that is transferred to the resist. In particular, substantially opaque regions of the reticle protect underlying regions of the resist from exposure to an energy source. The resist is, therefore, patterned by selectively exposing regions of the resist to an energy source such as ultraviolet light. The patterned resist may then be used to mask underlying layers in subsequent semiconductor fabrication processes such as ion implantation and etch. For example, a resist may substantially inhibit an underlying layer such as a dielectric material or the semiconductor substrate from implantation of ions or removal by etch.

As the feature sizes of semiconductor devices continue to shrink, the minimum feature size that may be successfully fabricated may often be limited by performance characteristics of a lithography process. Examples of performance characteristics of a lithography process include, but are not limited to, resolution capability, across chip linewidth variations, and across wafer linewidth variations. In optical lithography, performance characteristics such as resolution capability of the lithography process may often be limited by the quality of the resist application, the performance of the resist, the exposure tool, and the wavelength of light that is used to expose the resist. The ability to resolve a minimum feature size, however, may also be strongly dependent on other critical parameters of the lithography process such as a temperature of a post exposure bake (PEB) process or an exposure dose of an exposure process. As such, controlling the critical parameters of lithography processes is becoming increasingly important to the successful fabrication of semiconductor devices.

One strategy for improving the performance characteristics of a lithography process involves controlling and reducing variations in critical parameters of the lithography process. One critical parameter in a lithography process is the PEB temperature. For example, a chemical reaction in an exposed portion of a chemically amplified resist is driven and controlled by heating the resist subsequent to the exposure process. Such a resist may include, but is not limited to, a resin and a photo-acid generating (PAG) compound. In such a resist, the temperature of the PEB process drives generation and diffusion of a photo-generated acid in the resist that causes deblocking of the resin. Deblocking of the resin substantially alters the solubility of the resist such that it may be removed by exposure to an aqueous developer solution in a subsequent developing process. As such, temperature-controlled diffusion in the exposed resist affects physical dimensions of the remaining resist, or resolved patterned features. Furthermore, variations in temperature across a bake plate of a PEB process module may cause variations in the dimensions of the features at various positions on a wafer. Therefore, the resolution capability of a lithography process may be improved by reducing temperature variations across the bake plate of a PEB process module.

There are several disadvantages, however, in using currently available methods to improve the resolution capability of lithography processes. For example, currently available methods may not account for degradation in the uniformity of a critical parameter over time. For a PEB module, thermal relaxation of heating elements, contamination, or other performance variations may adversely affect the resolution capability of a lithography process to various degrees over time. As such, monitoring and controlling time-dependent variations in the critical parameters may maintain and improve the performance characteristics of a lithography process. In addition, integrated control mechanisms that may currently be used to monitor variations in the temperature of the PEB module may control and alter the process at the wafer level. Therefore, all positions, or fields, on the wafer are affected equally, and improvements are made for an average performance across the wafer. In this manner, systematic variations in the resolution capability from field to field across a wafer may not be monitored or altered, which may have an adverse affect on the overall performance characteristics of the lithography process.

Lithography track manufacturers have developed stable, well controlled, PEB plates. Some PEB plates include multiple heating elements such that the plate temperature (T) can be varied across the surface of the plate to compensate for across plate non-uniformity (systematic errors). However, by design, it is difficult to adjust the T across the plate (due to, for example, thermal mass, design, and the inability to correlate changes in T to end results (e.g., dimensions of patterned features) in the resist). Plate T inputs are generally selected based on characterization experiments using either product wafers or specific wafers that include T sensors, and the settings are fixed for a given product and layer.

Existing methods used to determine temperature set points do not take into account and therefore cannot compensate for the following phenomena: drifts in each plate (e.g., time variation in the temperature set point), interaction between plate and wafer that results in a local thermal history on the wafer that is different than that of the plate, and thermal history modifications that are due to prior steps (e.g. time between exposure of a wafer and the PEB step). In accordance with the plate design, currently available track configurations enable only the monitoring of the local thermal history of the plate and do not enable the monitoring of the wafer parameters (either T history or latent image critical dimension (CD) across the wafer). Therefore, although modifying the thermal history of the whole wafer by adjusting the bake time is possible, such modifications cannot improve across wafer (x-wafer) uniformity and will even degrade wafer mean uniformity (e.g., due to lack of correlation to actual wafer parameters).

In the literature, one can find several proposals for enabling wafer based control. For example, Sturtevant (1995, SPIE 2196) and U.S. Pat. No. 5,516,608 to Hobbs et al., which are incorporated by reference as if fully set forth herein, propose an apparatus (that is configured for 1st order diffraction measurements using a circular light emitting diode (LED) source) configured to measure the latent image (averaged over a relatively large area) of a memory wafer and to adjust bake time to compensate for the latent image signal. However, the level of control that can be achieved using this apparatus is limited because the apparatus is configured such that only one location on the wafer can be measured (i.e., the apparatus cannot measure x-wafer non uniformity) and uses a coherent, single wavelength source, which is sensitive to film stack variations and is, therefore, not a reliable measurement of the latent image.

Prins et al. (1996, SPIE 2725), which is incorporated by reference as if fully set forth herein, propose measuring the reflected light instead of the 1 st order diffracted light, but note that the reflected light is less sensitive to the latent image. Additional examples of currently used methods and systems are described by Friedberg et al. (SPIE 2004) and Smith et al. (2001, SPIE 4345), which are incorporated by reference as if fully set forth herein.

Accordingly, it may be advantageous to develop methods and systems for controlling variation in dimensions of patterned features across a wafer by compensating for non-time varying spatial variation in a temperature to which the wafer is exposed during a PEB step of a lithography process and one or more of time varying spatial variation in the temperature, variation in energy transfer to the wafer, and variation in time between an exposure step of the lithography process and initiation of the PEB step.

### SUMMARY OF THE INVENTION

The following description of various embodiments of methods and systems is not to be construed in any way as limiting the subject matter of the appended claims.

One embodiment relates to a method for controlling variation in dimensions of patterned features across a wafer. The method includes measuring a characteristic of a latent image formed in a resist at more than one location across a wafer during a lithography process. The method also includes altering a parameter of the lithography process in response to the characteristic to reduce variation in dimensions of patterned features formed across the wafer by the lithography process. Altering the parameter compensates for non-time varying spatial variation in a temperature to which the wafer is exposed during a post exposure bake (PEB) step of the lithography process and an additional variation in the PEB step.

In one embodiment, the additional variation includes time varying spatial variation in the temperature. In another embodiment, the additional variation includes variation in energy transfer to the wafer. In a further embodiment, the additional variation includes variation in time between an exposure step of the lithography process and initiation of the PEB step.

In one embodiment, the parameter includes the temperature to which different portions of the wafer are exposed during the PEB step. In another embodiment, the parameter includes a temperature to which different portions of the wafer are exposed during a bake step performed during the lithography process after the PEB step. In a further embodiment, the parameter includes a parameter of a develop step performed during the lithography process after the PEB step.

In some embodiments, measuring the characteristic includes optically measuring the characteristic of the latent image. In another embodiment, measuring the characteristic includes optically measuring the characteristic of the latent image at more than one wavelength. In a further embodiment, measuring the characteristic includes optically measuring the characteristic of the latent image across a spectrum of wavelengths. In an additional embodiment, measuring the characteristic includes optically forming an image of the latent image and determining the characteristic from the image. In other embodiments, measuring the characteristic includes measuring byproducts of the PEB step and determining the characteristic from the byproducts.

In some embodiments, measuring the characteristic includes measuring the characteristic of the latent image at the more than one location sequentially. In a different embodiment, measuring the characteristic includes measuring the characteristic of the latent image at the more than one location simultaneously. In a further embodiment, measuring the characteristic includes measuring the characteristic of the latent image during the PEB step. Each of the embodiments of the method described above may include any other step(s) described herein.

Another embodiment relates to a system configured to control variation in dimensions of patterned features across a wafer. The system includes a device configured to measure a characteristic of a latent image formed in a resist at more than one location across a wafer during a lithography process. The system also includes a control subsystem configured to alter a parameter of the lithography process in response to the characteristic to reduce variation in dimensions of patterned features formed across the wafer by the lithography process. Altering the parameter compensates for non-time varying spatial variation in a temperature to which the wafer is exposed during a PEB step of the lithography process and an additional variation in the PEB step.

In one embodiment, the additional variation includes time varying spatial variation in the temperature. In another embodiment, the additional variation includes variation in energy transfer to the wafer. In a further embodiment, the additional variation includes variation in time between an exposure step of the lithography process and initiation of the PEB step.

In one embodiment, the parameter includes the temperature to which different portions of the wafer are exposed during the PEB step. In another embodiment, the parameter includes a temperature to which different portions of the wafer are exposed during a bake step performed during the lithography process after the PEB step. In a further embodiment, the parameter includes a parameter of a develop step performed during the lithography process after the PEB step.

In one embodiment, the device includes an optical device. In another embodiment, the device is configured to measure the characteristic of the latent image at more than one wavelength. In a further embodiment, the device is configured to measure the characteristic of the latent image across a spectrum of wavelengths. In an additional embodiment, the device is configured to optically form an image of the latent image and to determine the characteristic from the image. In other embodiments, the device is configured to measure byproducts of the PEB step and to determine the characteristic of the latent image from the byproducts.

In one embodiment, the device is configured to measure the characteristic of the latent image at the more than one location sequentially. In a different embodiment, the device is configured to measure the characteristic of the latent image at the more than one location simultaneously. In a further embodiment, the device is configured to measure the characteristic of the latent image during the PEB step. Each of the embodiments of the system described above may be further configured as described herein.

### BRIEF DESCRIPTION OF THE DRAWINGS

Further advantages of the present invention may become apparent to those skilled in the art with the benefit of the following detailed description of the preferred embodiments and upon reference to the accompanying drawings in which:

FIG. 1 is a schematic diagram illustrating a cross-sectional view of one embodiment of a system configured to control variation in dimensions of patterned features across a wafer;

FIG. 2 is a schematic diagram illustrating a cross-sectional view of one example of a latent image formed in a resist on a wafer;

FIGS. 3-5 are schematic diagrams illustrating a cross-sectional view of various embodiments of a device configured to measure a characteristic of a latent image formed in a resist at more than one location across a wafer during a lithography process;

FIG. 6 is a schematic diagram illustrating a top view of one embodiment of a bake plate configured such that a parameter of the bake plate can be altered according to embodiments described herein; and

FIG. 7 is a schematic diagram illustrating a cross-sectional view of one example of patterned features formed across a wafer.

While the invention is susceptible to various modifications and alternative forms, specific embodiments thereof are shown by way of example in the drawings and may herein be described in detail. The drawings may not be to scale. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

As used herein, the term “wafer” generally refers to substrates formed of a semiconductor or non-semiconductor material. Examples of such a semiconductor or non-semiconductor material include, but are not limited to, monocrystalline silicon, gallium arsenide, and indium phosphide. Such substrates may be commonly found and/or processed in semiconductor fabrication facilities.

A wafer may include one or more layers formed upon a substrate. For example, such layers may include, but are not limited to, a resist, a dielectric material, and a conductive material. The terms “resist” and “photoresist” are used interchangeably herein. Many different types of such layers are known in the art, and the term wafer as used herein is intended to encompass a wafer including all types of such layers.

One or more layers formed on a wafer may be patterned. For example, a wafer may include a plurality of dies, each having repeatable patterned features. Formation and processing of such layers of material may ultimately result in completed devices. Many different types of devices may be formed on a wafer, and the term wafer as used herein is intended to encompass a wafer on which any type of device known in the art is being fabricated.

Turning now to the drawings, it is noted that the figures are not drawn to scale. In particular, the scale of some of the elements of the figures is greatly exaggerated to emphasize characteristics of the elements. It is also noted that the figures are not drawn to the same scale. Elements shown in more than one figure that may be similarly configured have been indicated using the same reference numerals.

In general, an embodiment of a system configured to control variation in dimensions (e.g., line width) of patterned features across a wafer includes a device and a control subsystem. The device is configured to measure a characteristic of a latent image formed in a resist at more than one location across a wafer during a lithography process. The control subsystem is configured to alter a parameter of the lithography process in response to the characteristic to reduce variation in dimensions of patterned features formed across the wafer by the lithography process. Altering the parameter compensates for non-time varying spatial variation in a temperature to which the wafer is exposed during a post exposure bake (PEB) step of the lithography process and an additional variation in the PEB step.

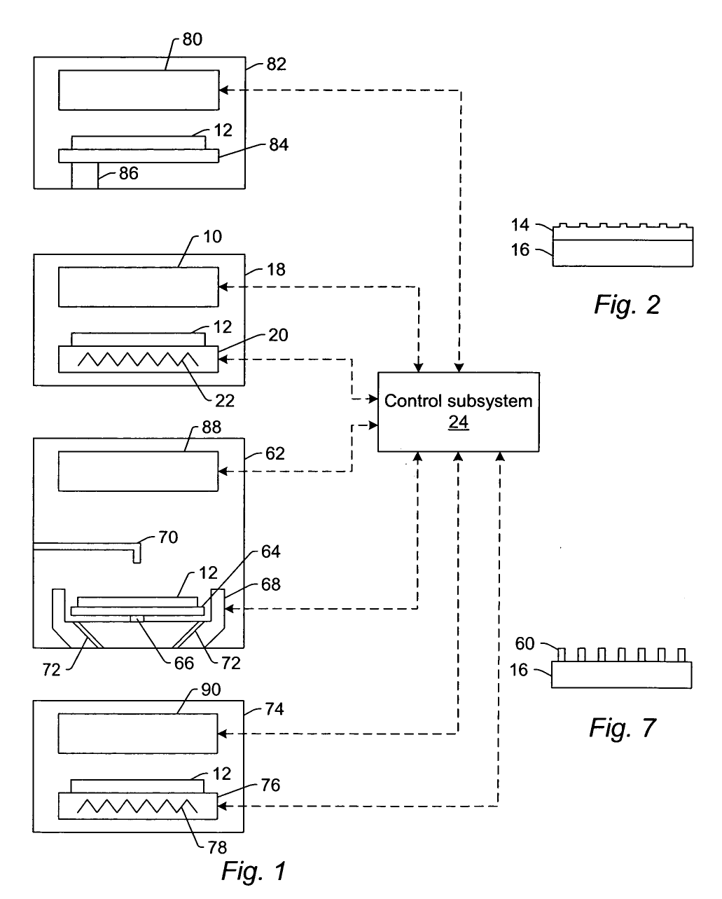

One embodiment of such a system is shown in FIG. 1. As shown in FIG. 1, the system includes device 10. Device 10 is configured to measure a characteristic of a latent image formed in a resist at more than one location across wafer 12 during a lithography process. A latent image or a “relief image” is generally defined by variations in the thickness of a resist across the resist after exposure of the resist and before development of the resist. For instance, after exposure, the exposed areas of the resist may have a thickness that is less than the thickness of non-exposed areas of the resist due to a reaction that takes place in the exposed areas during the exposure step. One example of a latent image formed in a resist is shown in FIG. 2. In particular, resist 14 formed on wafer 16 has varying thickness across the wafer. Areas of resist 14 that have a reduced thickness include areas of the resist that were exposed to an energy source by an exposure tool (e.g., a scanner or a stepper).

The characteristic(s) of the latent image may be relatively constant between exposure and initiation of the PEB step. During the PEB step, however, one or more characteristics of the latent image may change. For instance, the thickness of areas of resist 14 that have a reduced thickness subsequent to exposure may be further reduced by one or more reactions in the resist that are caused by the energy to which the wafer is exposed during the PEB step. One or more characteristics of the latent image formed in resist 14 may be measured by device 10. The characteristic(s) of the latent image that may be measured by device 10 may include any characteristic(s) of the latent image described herein. In addition, device 10 may be further configured as described herein.

As shown in FIG. 1, device 10 may be incorporated into (i.e., disposed within) PEB module 18. Therefore, in one embodiment, device 10 is configured to measure one or more characteristic(s) of the latent image during the PEB step performed on wafer 12. For instance, PEB module 18 includes PEB plate 20 on which wafer 12 is positioned during the PEB step. PEB plate 20 may be further configured as described herein. For instance, although PEB plate 20 is generally shown in FIG. 1 as including resistive heating element 22 that is configured to generate the heat to which wafer 12 is exposed during the PEB step, it is to be understood that PEB plate 20 may include multiple resistive or other heating elements (not shown in FIG. 1) that may be further configured as described herein.

While wafer 12 is positioned on PEB plate 20, device 10 can perform the measurements described herein. Device 10 is, therefore, configured to perform in situ measurements of the characteristic(s) of the latent image. In addition, device 10 may be configured to perform in situ measurements of the characteristic(s) of the latent image at various times during the PEB step. In this manner, the device may configured to generate measurements that are sensitive to the changes in the latent image during the PEB step. Therefore, the one or more characteristics of the latent image can be monitored continuously or intermittently during the PEB step. However, device 10 may be configured to perform measurements of the latent image before the PEB step (e.g., immediately after the wafer is moved into PEB module 18) or after the PEB step (e.g., before the wafer is removed from PEB module 18). As described further herein, device 10 can be used for monitoring of latent image x-wafer signatures using sensor types that have not been previously used for latent image measurements that are performed before, during, and/or after the PEB step.

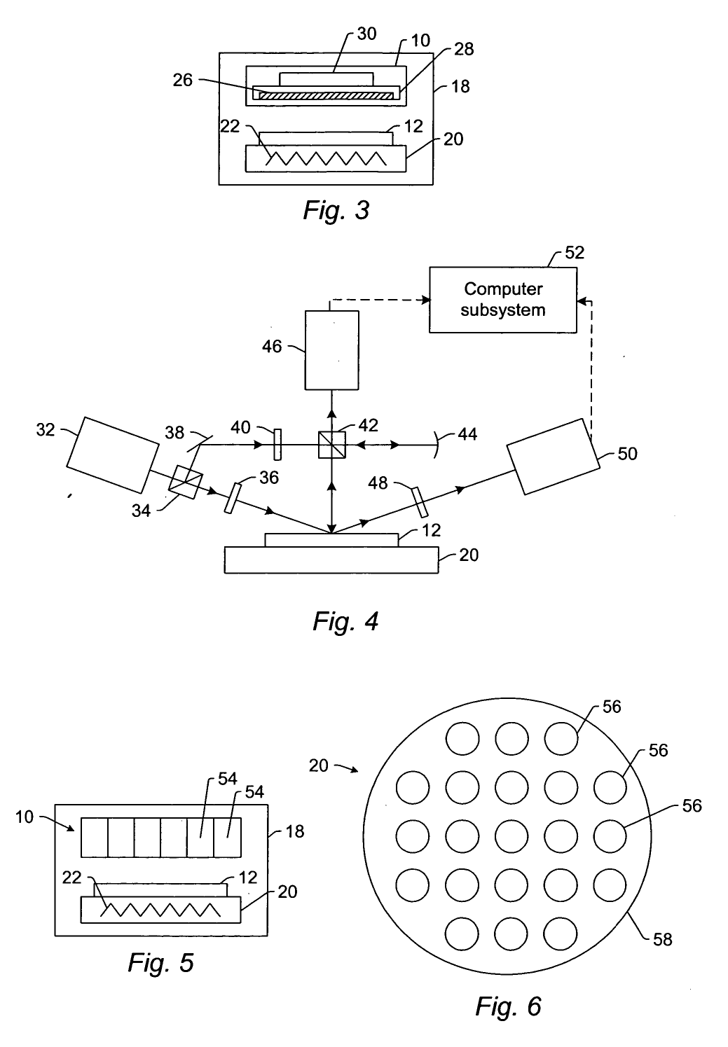

In one embodiment, device 10 is configured to measure byproducts of the PEB step and to determine the characteristic of the latent image from the byproducts. One such embodiment of device 10 is shown in FIG. 3. The device shown in FIG. 3 includes sensor 26 that is configured to detect and measure byproducts of the PEB step performed on wafer 12. For example, sensor 26 may be configured to detect byproducts (e.g., volatile organic materials) that are outgassed from the resist formed on wafer 12 during the PEB step. In this manner, outgassing above PEB plate 20 can be measured during and/or after the PEB step. Therefore, the measurements described herein can be performed by measuring byproducts produced during the PEB step. In another example, sensor 26 may be configured to detect materials deposited on the surface of the sensor during the PEB step. The deposited byproducts can be measured during and/or after the PEB step. In this manner, the device may be configured to perform the measurements using chemical composition monitoring of the wafer. Sensor 26 may include any sensor that can be used to detect a presence of materials, a quantity of materials, the composition of materials, etc. produced during the PEB step.

Although sensor 26 is shown to have a lateral dimension (e.g., a width or a length) that is about the same as the width of wafer 12, it is to be understood that sensor 26 may have any suitable dimensions known in the art. In addition, although sensor 26 is shown in FIG. 3 to be disposed above wafer 12, it is to be understood that sensor 26 may be positioned at any suitable location within PEB module 18. Alternatively, sensor 26 may not be disposed within PEB module 18. Instead, sensor 26 may be located in a conduit or other structure coupled to the PEB module through which byproducts of the PEB step are removed from the PEB module.

Sensor 26 may be disposed within housing 28. Housing 28 may be configured to maintain a position of sensor 26 within PEB module 18. Housing 28 may have any suitable configuration known in the art. One or more components (not shown) may also be disposed in housing 28 such as components that are configured to couple sensor 26 to one or more electronic components 30 such as a computer subsystem. The one or more electronic components 30 may be configured to provide an interface between sensor 26 and the control subsystem (not shown in FIG. 3).

In another embodiment, device 10 shown in FIG. 1 also or alternatively includes an optical device. In some embodiments, the device is configured to measure the characteristic of the latent image at more than one wavelength. In another embodiment, the device is configured to measure the characteristic of the latent image across a spectrum of wavelengths. In an additional embodiment, the device is configured to optically form an image of the latent image and to determine the characteristic from the image. The device may be configured to perform the measurements using scatterometry, ellipsometry, reflectometry, polarized reflectometry, interferometry, or some combination thereof.

One embodiment of a device that can be used to perform the measurements described herein is shown in FIG. 4. The device shown in FIG. 4 includes light source 32. Light source 32 may include a single wavelength light source such as a laser. However, in many instances, it may be advantageous for the device to be configured to perform measurements at more than one wavelength. In one such instance, light source 32 may include a polychromatic light source such as a multi-wavelength laser if the device is configured to measure the characteristic of the latent image at more than one wavelength. In another alternative, light source 32 may include a broadband light source such as an arc lamp if the device is configured to measure the characteristic of the latent image across a spectrum of wavelengths. Light source 32 may include any other suitable light source known in the art.

Light from light source 32 may be directed to wafer 12 at an oblique angle of incidence. In some embodiments, light from light source 32 may also or alternatively be directed to wafer 12 at a normal angle of incidence. For instance, the device may include beam splitter 34. Beam splitter 34 may include any suitable beam splitter known in the art. Beam splitter 34 may transmit a portion of the light from light source 32 to polarizing component 36. Polarizing component 36 may include any suitable polarizing component known in the art. Light transmitted by polarizing component is directed to wafer 12 at an oblique angle of incidence. The oblique angle of incidence may be any suitable oblique angle of incidence known in the art.

Beam splitter 34 may reflect the other portion of the light from light source 32 to reflective optical component 38. Reflective optical component 38 may include any suitable reflective optical component known in the art such as a flat mirror. Reflective optical component 38 is configured to direct the light through polarizing component 40 to beam splitter 42. Polarizing component 40 may include any suitable polarizing component known in the art. Beam splitter 42 may include any suitable beam splitter known in the art. Beam splitter 42 may reflect a portion of the light to wafer 12 at a substantially normal angle of incidence. Beam splitter 42 may also transmit a portion of the light to reflective optical component 44. Reflective optical component 44 may include any suitable reflective optical component known in the art such as a curved mirror.

Normal incidence illumination reflected from wafer 12 may be transmitted by beam splitter 42 to detector 46. Light reflected from reflective optical component 44 may be reflected by beam splitter 42 to detector 46. The device may also include polarizing component 48 through which oblique incidence illumination reflected or scattered from wafer 12 may pass. Polarizing component 48 may include any suitable polarizing component known in the art. Light that passes through polarizing component 48 is detected by detector 50.

Detectors 46 and 50 may be selected based on the wavelength(s) used for the measurements. In addition, the detectors may be selected based on the type of measurements to be performed by the device. For instance, the detectors may include imaging detectors if the device is configured to optically form an image of the latent image.

Detectors 46 and 50 are coupled to computer subsystem 52 via transmission media shown by the dashed lines in FIG. 4. The transmission media may include any suitable transmission media known in the art. In this manner, the computer subsystem may receive output signals generated by detectors 46 and 50. Computer subsystem 52 may also be configured to use the output signals to determine one or more characteristics of the latent image.

Computer subsystem 52 may take various forms, including a personal computer system, mainframe computer system, workstation, image computer, parallel processor, or any other device known in the art. In general, the term “computer system” may be broadly defined to encompass any device having one or more processors, which executes instructions from a memory medium. Computer subsystem 52 may be further configured as described herein.

The components of the device shown in FIG. 4 that are included in a particular embodiment of the device or are used for a particular measurement can vary depending on the measurement technique or techniques that are selected. For instance, as described above, the device may be configured to perform measurements of a latent image formed on wafer 12 using scatterometry, ellipsometry, reflectometry, polarized reflectometry, interferometry, or some combination thereof.

In one such embodiment, if the device is configured to perform scatterometry measurements, the device may be configured to direct light from light source 32 to wafer 12 at an oblique angle of incidence. In this embodiment, beam splitter 34 and polarizing component 36 may not be included in the device or may be moved out of the illumination path of the device during these measurements. In addition, in this embodiment, polarizing component 48 may not be included in the device or may be moved out of the collection path of the device during these measurements. Light scattered from the wafer is detected by detector 50. In particular, light scattered by the features of the latent images into one or more diffraction orders may be detected by detector 50. In this manner, output signals generated by detector 50 are scatterometry measurements of the latent image. The device may be configured to perform the scatterometry measurements at a single wavelength, at more than one wavelength, or across a spectrum of wavelengths (i.e., spectroscopic scatterometry).

In another such embodiment, if the device is configured to perform ellipsometry measurements, the device may be configured to direct light from light source 32 through polarizing component 36 to wafer 12 at an oblique angle of incidence. Therefore, polarizing component 36 may be configured to function as a polarizer in this embodiment. In this embodiment, beam splitter 34 may not be included in the device or may be moved out of the illumination path during these measurements. Light reflected from the wafer passes through polarizing component 48 and is detected by detector 50. Therefore, polarizing component 48 may be configured to function as an analyzer in this embodiment, and output signals generated by detector 50 include ellipsometry measurements. The device may be configured such that polarizing component 36 or polarizing component 48 rotates during these measurements. Therefore, the device may be configured as a rotating polarizer ellipsometer or a rotating analyzer ellipsometer. In addition, the device may be configured to perform the ellipsometry measurements at a single wavelength, at more than one wavelength, or across a spectrum of wavelengths (i.e., spectroscopic ellipsometry).

In a further embodiment, if the device is configured to perform reflectometry measurements, the device may be configured to direct light from light source 32 to beam splitter 34. Light that is reflected by beam splitter 34 is directed to reflective optical component 38. Reflective optical component 38 directs the light to beam splitter 42. In this embodiment, polarizing component 40 may not be included in the device or may be moved out of the illumination path during the reflectometry measurements. Light reflected by beam splitter 42 is directed to wafer 12 at a substantially normal angle of incidence. In this embodiment, beam splitter 42 may not be configured to transmit a portion of the illumination to reflective optical component 44, or reflective optical component 44 may not be included in the device. Normal incidence illumination that is specularly reflected by wafer 12 passes through beam splitter 42 and is detected by detector 46. In this manner, output signals generated by detector 46 include reflectometry measurements of the latent image. The device may be configured to perform the reflectometry measurements at a single wavelength, at more than one wavelength, or across a spectrum of wavelengths (i.e., spectroscopic reflectometry).

In another embodiment, if the device is configured to perform polarized reflectometry, the device may be configured as described for reflectometry measurements. However, for polarized reflectometry measurements, polarizing component 40 may be disposed in the illumination path as shown in FIG. 4. In this embodiment, polarizing component 40 may be configured such that light can be directed to wafer 12 at a selected polarization or at a variety of polarizations. In this manner, output signals generated by detector 46 include polarized reflectometry measurements of the latent image. The device may be configured to perform the polarized reflectometry measurements at a single wavelength, at more than one wavelength, or across a spectrum of wavelengths (i.e., spectroscopic polarized reflectometry).

In some embodiments, if the device is configured to perform interferometry measurements of the wafer, the device may be configured to direct light from light source 32 to beam splitter 34. Light that is reflected by beam splitter 34 is directed to reflective optical component 38. Reflective optical component 38 directs the light to beam splitter 42. In this embodiment, polarizing component 40 may not be included in the device or may be moved out of the illumination path during the interferometry measurements. Light reflected by beam splitter 42 is directed to wafer 12 at a substantially normal angle of incidence. Light transmitted by beam splitter is directed to reflective optical component 44. Light reflected by the wafer is transmitted through beam splitter 42. In addition, light reflected from reflective optical component 44 is reflected by beam splitter 42. Therefore, the light reflected by the wafer and the light reflected by optical component 44 may interfere, and the interference between the two beams of light can be detected by detector 46. In this manner, output signals generated by detector 46 can include interferometry measurements of the latent image. The device may be configured to perform the interferometry measurements at a single wavelength, at more than one wavelength, or across a spectrum of wavelengths.

The device shown in FIG. 4 may also or alternatively be configured as a “correlation spectrometer.” In this manner, a correlation spectrometer may also or alternatively be used for the measurements described herein. Examples of a correlation spectrometer are described in U.S. Pat. No. 4,355,903 to Sandercock and U.S. Pat. No. 5,241,366 to Bevis et al., which are incorporated by reference as if fully set forth herein. The rotating disk of the spectrometers described in these patents can also be replaced by a simpler apparatus which uses a translator (such as a piezoelectric translator) to change the distance between a mirror and a beam splitter in the optical path. The embodiments of the device described herein may be further configured as described in these patents.

The device shown in FIG. 4 is, therefore, advantageously configured to perform different types of measurements of wafer 12 including scatterometry, ellipsometry, reflectometry, polarized reflectometry, and interferometry measurements by altering the position of one or more of the components of the device shown in FIG. 4. Such a configuration is advantageous since multiple types of measurements may be used in combination to determine more characteristics or more accurate characteristics of the latent image. Of course, device 10 may be configured to perform only a subset of these measurement techniques. For example, device 10 may be configured for scatterometry and ellipsometry measurements of the latent image. In another example, device 10 may be configured for reflectometry and interferometry measurements of the latent image. In addition, device 10 may be configured to perform two or more of any of the measurement techniques described herein on the latent image formed on wafer 12.

Furthermore, although one configuration of the device is shown in FIG. 4, it is to be understood that various changes can be made to the device, and the device will still be configured within the scope of the embodiments described herein. For instance, one or more lenses (not shown) may be positioned in the illumination paths and the collection paths of the device. In addition, the angles and the spacings between the optical components may be varied from that shown in FIG. 4, for example, to optimize performance of the device. The single light source shown in FIG. 4 may also be replaced by multiple light sources (not shown) (e.g., one for normal incidence illumination and one for oblique incidence illumination). The multiple light sources may be light sources of the same or different types.

As described above, the device may be configured to perform measurements of a latent image formed on a wafer using spectral methods. Data from spectral methods can be analyzed by computer subsystem 52 in several ways. For example, full data analysis can be performed in the same manner in which scatterometry critical dimension (CD) measurements are performed. Alternatively, relative methods can be used to track changes in the acquired spectra over time. One such relative method includes comparing peak shifts measured at one or more different locations on the wafer to predetermined spectra such as previously acquired spectra or calculated spectra. The spectra measured at different sites may optionally be used in such measurements to make the measurements more robust.

In one such example, at each measurement site, the reflectivity may be measured as function of wavelength (λ). In this example, Fourier transforming may be used to identify the peak(s) that relate(s) to film thickness(es) (resist and any underlying films). In addition, the shift and/or widening of the peak(s) may be monitored as the PEB step progresses and causes a latent image to be created on the wafer. In other words, the shift and/or widening of the peak(s) can be used to determine the progress of the PEB step since the changes in the peak(s) are indicative of chemical and/or physical changes in the resist. The method may also include correcting for dispersion (e.g., changes in index of refraction as function of wavelength) to obtain sharper peaks thereby allowing more sensitive detection of broadening and shift.

The device may also be configured to perform the above described measurements at selected, specific wavelengths at which constituents of the resist (such as solvent, photo-active generating (PAG) compound, etc.) exhibit particularly pronounced absorption or refraction. The device embodiments described herein may also be configured to perform the measurements by directly monitoring the chemical composition of the resist or byproducts of PEB step using laser diodes (not shown).

As described above, the device may be configured to optically form an image of the latent image. In particular, measurement data can be collected as one or more one-dimensional or two-dimensional images. In such embodiments, the characteristic(s) of the latent image can be determined from the image. For example, by analyzing the intensity/pixel number as a function of path difference, the peak change and/or broadening can be monitored (like the reflectometry embodiment described above) as the relief or latent image is created in the resist during the PEB step. In addition, individual pixels or groups of pixels can be analyzed to characterize cross wafer uniformity.

The device may be configured to perform measurements on a test structure in the latent image, a die in the latent image, or the latent image formed across the whole wafer. In addition, the systems described herein may be configured to select an area to analyze from the whole field of view (FOV) of the measurement device.

Device 10 may be configured to measure the characteristic(s) of the latent image formed in the resist at more than one location across wafer 12 during the PEB step of a lithography process performed on wafer 12. Device 10 may be configured to measure the characteristic(s) at more than one location across wafer 12 in any suitable manner known in the art. For example, as described further herein, the measurements can be made at more than one discrete location across the wafer either sequentially (e.g., by moving the wafer (via movement of the PEB plate) and/or the measurement head) or in parallel (e.g., using multiple measurement heads).

Measuring the characteristic(s) of the latent image at more than one location across the wafer is advantageous for a number of reasons. For example, for measurements performed using scatterometry, the device can measure test sites across the wafer such that the measurements are responsive to the changes in surface topography of the resist and modulation of optical properties of the resist as the latent image develops on the wafer during the PEB step. The parameter of interest is mostly the depth (or height) of features in the latent image in the resist; and therefore, the scatterometry measurements can be relatively simple and similar to the spectral methods above. In another example, for measurements performed using common path interferometry, similar to above, the device can be configured to measure either a whole die or test structures that can be identified from the entire FOV of the measurement device.

In some embodiments, device 10 is configured to measure the characteristic(s) of the latent image at the more than one location sequentially. Sequential measurements at multiple locations across a wafer may be achieved in a number of ways. For instance, the device may be configured to alter the location at which the FOV of the device is positioned on wafer 12. Altering the location of the FOV of the device on the wafer may be performed by physically altering the position of device 10 above wafer 12. Physically altering the position of device 10 may be performed in any suitable manner known in the art. Alternatively, altering the location of the FOV of the device on the wafer may be performed by optical components (not shown in FIG. 1) included in the device such as a acousto-optic deflector (AOD) or any other suitable mechanical or optical scanning component known in the art.

Altering the location of the FOV of the device on wafer 12 may also or alternatively be performed by altering a position of the wafer within PEB module 18. For example, PEB plate 20 may be coupled to an assembly (not shown) that may be configured to mechanically or robotically alter the position of PEB plate 20 within PEB module 18 and therefore the position of wafer 12 within PEB module 18. The assembly may include any suitable mechanical or robotic assembly known in the art. The assembly may be controlled by device 10 (e.g., by a computer subsystem (not shown in FIG. 1) of the device, which may be configured as described herein) or another control subsystem of the system (e.g., control subsystem 24).

In a different embodiment, device 10 is configured to measure the characteristic(s) of the latent image at more than one location across wafer 12 simultaneously. For instance, device 10 may be configured as a multi-spot device. In other words, device 10 may be configured to direct light to and collect light from multiple locations on the wafer simultaneously such that measurements can be performed at the multiple locations simultaneously. In one such example, multiple spots on the wafer may be illuminated using a diffractive optical element (not shown) positioned in the illumination path of the device, and light collected from the illuminated spots may be detected by an array of detectors (not shown) or a detector such as detect 46 or 50 having an array of photosensitive elements.

In a different embodiment, device 10 may include multiple measurement subsystems (not shown in FIG. 1), each of which may be used to measure the characteristic(s) of the latent image at multiple locations on wafer 12 in parallel. One such embodiment of device 10 is illustrated in FIG. 5. In particular, as shown in FIG. 5, one embodiment of device 10 includes multiple measurement subsystems 54. Each of the measurement subsystems (or “measurement heads”) may be configured to measure the characteristic(s) of the latent image at a different location on the wafer. In this manner, some or all of the measurement subsystems may perform measurements on the wafer simultaneously. Each of the measurements subsystems may be configured similarly. In addition, each of the measurement subsystems may be configured to perform one or more of the measurement techniques described herein. Furthermore, each of the measurement subsystems may be coupled to a computer subsystem (not shown in FIG. 5) such as computer subsystem 50 described further above. In this manner, the computer subsystem may be configured to use measurements performed by each of the measurement subsystems to alter the parameter of the lithography process as described further herein.

As shown in FIG. 5, the measurement subsystems may be arranged in a one-dimensional array. In one such embodiment, the one-dimensional array of measurement subsystems may be configured such that the position of the one-dimensional array of measurement subsystems can be altered with respect to wafer 12. In this manner, each of the measurement subsystems in the array can measure the characteristic(s) of the latent image at more than one location on the wafer sequentially. In other words, the position of the one-dimensional array may be altered with respect to wafer 12 such that the one-dimensional array of measurement subsystems scans across the wafer (e.g., in a stepwise manner). In a different embodiment, the device may include a two-dimensional array (not shown) of measurement subsystems. The two-dimensional array of measurement subsystems may or may not span an entire area of the wafer. In addition, the position of the two-dimensional array of measurement subsystems may or may not be altered as described above.

Furthermore, although the device is shown in FIG. 5 as including a particular number of measurement subsystems, it is to be understood that the device may include any suitable number of measurement subsystems configured in any suitable arrangement. Although the embodiment of the device shown in FIG. 5 is incorporated into PEB module 18, it is to be understood that such a device may be coupled to a lithography tool in any other manner described herein such that the device can perform measurements of the latent image at other points during the lithography process.

Incorporating device 10 into PEB module 18 may be advantageous for a number of reasons. For instance, since device 10 is configured to measure characteristic(s) of the latent image formed on wafer 12 during the PEB step at more than one location across wafer 12, the measurements are sensitive to all variations in the parameters of the PEB step. In particular, the measurements are sensitive to non-time varying spatial variation in a temperature to which wafer 12 is exposed during the PEB step of the lithography process. The measurements are also sensitive to additional variations in the PEB step including time varying spatial variation in the temperature, variation in energy transfer to the wafer, and variation in time between an exposure step of the lithography process and initiation of the PEB step. As such, the measurements can be used to control the parameters of the PEB step (and/or possibly other step(s) of the lithography process as described further herein) to compensate for these variations.

In particular, control subsystem 24 is configured to alter a parameter of the lithography process in response to the characteristic of the latent image to reduce variation in dimensions of patterned features formed across the wafer by the lithography process. As shown in FIG. 1, control subsystem 24 may not be included in device 10. In other words, control subsystem may be external to device 10. Such an embodiment of the control subsystem may be advantageous in instances such as when device 10 is incorporated into PEB module 18 or another process module of a lithography tool. In this manner, space within the module or modules is not occupied by control subsystem 24. Instead, control subsystem 24 may be coupled to device 10 by a transmission medium (shown in FIG. 1 by the dashed line). The transmission medium may include any suitable transmission medium known in the art. The device may send measurement results to the control subsystem via the transmission medium. In addition, the control subsystem may send one or more instructions to the device via the transmission medium. In this manner, the control subsystem may be configured to alter and control one or more parameters of the device.

As described above, therefore, control subsystem 24 may be configured to receive measurements of the latent image from device 10. Control subsystem 24 may use the measurements to determine if and how one or more parameters of the lithography process can or should be altered to reduce and control variation in dimensions of patterned features formed across wafer 12. For instance, control subsystem 24 may be configured to alter one or more parameters of PEB plate 20. Control subsystem 24 may be coupled to PEB plate 20 by a transmission medium (as shown in FIG. 1 by the dashed line). Control subsystem 24 may be configured to alter the one or more parameters of PEB plate 20 directly (by directly controlling a component of the PEB plate) or indirectly (by sending the one or more parameter alterations to a local control subsystem of the PEB plate).

As described above, therefore, control subsystem 24 receives measurements from device 10 that are sensitive to non-time varying spatial variation in a temperature to which the wafer is exposed during a PEB step of the lithography process, time varying spatial variation in the temperature, variation in energy transfer to the wafer, and variation in time between an exposure step of the lithography process and initiation of the PEB step. Since control subsystem 24 determines which parameter(s) and how the parameter(s) of the lithography process are to be altered in response to the characteristic, altering parameter(s) as described above compensates for the variations to which the measurements are sensitive. In particular, altering the parameter(s) compensates for non-time varying spatial variation in a temperature to which the wafer is exposed during a PEB step of the lithography process and an additional variation in the PEB step. The additional variation includes time varying spatial variation in the temperature, variation in energy transfer to the wafer, and variation in time between an exposure step of the lithography process and initiation of the PEB step.

The control subsystem may be configured to determine the parameter(s) of the lithography process that are to be altered in any manner (e.g., using any suitable method, algorithm, data structure, etc.). For instance, the control subsystem may receive latent image thickness (e.g., average thickness) measured at multiple locations on the wafer. Based on the latent image thickness measured at one location on the wafer and a predetermined relationship between total energy transferred to the wafer during the PEB step (which may be correlated to the temperature to which that location of the wafer is exposed during the PEB step) and the final latent image thickness (which may be correlated to the dimensions of patterned features formed across the wafer), the control subsystem may be configured to determine the temperature to which that location on the wafer should be exposed during the PEB step. In addition, the control subsystem may be configured to determine the temperature to which that location on the wafer should be exposed throughout the PEB step (i.e., temperature as a function of time).

The predetermined relationship may be determined experimentally or empirically. The predetermined relationship may also be defined, stored, and used in any suitable format known in the art. Obviously, the example of how the control subsystem can determine a parameter of the PEB step from the characteristic described above is only one example of the how one measured latent image characteristic can be used to determine a parameter of the lithography process to be altered. The embodiments described herein can be used to alter any parameter of the lithography process that has some effect on the dimensions of patterned features formed across the wafer by the lithography process and that can be correlated to a characteristic of the latent image that can be measured by the device.

In some embodiments, therefore, the parameter that is altered by the control subsystem includes the temperature to which different portions of the wafer are exposed during the PEB step. For example, the measurement data collected by the device can be used to change the x-wafer bake process (e.g., using a dynamic plate design) while baking using an in situ control technique. In addition, or alternatively, as described further herein, the measurement data collected by the device can be used to alter one or more parameters of either an additional bake step (preferably, but optionally, with the ability to locally modify the heating of the wafer during the additional bake step) or a develop step using a feedforward (FF) control technique.

One embodiment of a PEB plate that can be used to alter the temperature to which different portions of the wafer are exposed during the PEB step is shown in FIG. 6. As shown in FIG. 6, PEB plate 20 includes multiple heating elements 56 disposed within plate substrate 58. Heating elements 56 may be resistive heating elements or any other suitable heating elements known in the art. Although a certain number and arrangement of heating elements 56 are shown in FIG. 6, it is to be understood that any suitable number of heating elements configured in any suitable arrangement may be included in PEB plate 20. Plate substrate 58 may be formed of any suitable material known in the art. The temperature of each of the multiple heating elements may be independently controlled by control subsystem 24 shown in FIG. 1. In this manner, the temperature to which different portions of the wafer are exposed may be independently controlled by the control subsystem.

In general, therefore, the systems described herein can be used to control the repeatability and uniformity of pattern profiles formed by a lithography process. In particular, the systems described herein can be used to reduce variation in the dimensions of patterned features formed by a lithography process by monitoring the progress of the reaction that takes place during the PEB step (e.g., by monitoring one or more parameters of the latent image during the PEB step) using one or more in situ sensors (or one or more in situ measurement devices) and optionally actively controlling the energy delivered to the wafer during the PEB step. The measurement device(s) may be further configured as described herein.

The primary sources of CD variations for 248 nm and 193 nm lithography are variations in one or more parameters of the exposure tool (e.g., a scanner) such as exposure dose, lens aberrations, and focal plane and one or more parameters of the lithography track such as variations in PEB time and temperature and photoresist development rate. PEB variation can be further partitioned into temporal and spatial variation of the PEB plate temperature and variation in the time between exposure and initiation of PEB. Reducing PEB variation is critical to lithographic CD control because of the high sensitivity of photoresist feature dimensions to PEB temperature (up to about 7 nm/C to about 8 nm/C).

The systems described herein can be used to correct for non-time varying spatial variation in the plate temperature similar to current methods. In addition, unlike currently used systems, the systems described herein can be used to correct for time varying spatial variation in plate temperature, variation in energy transfer from plate to wafer, and variation in photoresist reaction rate due to variation in the delay between exposure and initiation of PEB. Therefore, the systems described herein can be used to compensate for all factors that contribute to variation in reaction progress of a photoresist during the PEB step, including those which change with time or are driven by interaction of individual wafers with the PEB plate. These phenomena cannot be corrected using current technologies. In particular, current methods can only compensate for steady-state spatial variation in the PEB temperature. Furthermore, the systems described herein can be used to perform measurements at more than one measurement location across the wafer, not just at one location. In addition, the systems described herein can use more accurate methods to measure the latent image relief signature.

Therefore, the systems described herein have several advantages over currently used systems. For example, the systems described herein provide improved uniformity of dimensions of patterned features formed across a wafer and improved repeatability of dimensions of patterned features formed on more than one wafer. As such, the systems described herein can be used to reduce variation in the dimensions of circuit features defined by photolithography. In general, this enables improvements in both integrated circuit (IC) product performance and yield. In addition, by implementing the systems described herein, an equipment manufacturer can secure a substantial competitive advantage for a photoresist coat/develop track.

The systems described herein also enable new use cases for the collected data (modify one or more parameters of the PEB step, an additional bake step, or a develop step). For example, one or more parameters of a develop step and/or an additional bake step of the lithography process may be altered in response to the one or more characteristics of the latent image that are measured before, during, and/or after the PEB step. For example, control subsystem 24 shown in FIG. 1 may be configured to alter a parameter of a develop step performed during the lithography process after the PEB step. In this manner, the control subsystem may be configured to alter one or more parameters of the develop step using a feedforward control technique.

During the develop step, the portions of the resist that were or were not exposed (depending on whether the resist is a “positive” resist or a “negative” resist) during the exposure step may be removed by exposure to one or more chemicals (e.g., a developer). In this manner, subsequent to the develop step, patterned features 60 are formed on wafer 16 as shown in FIG. 7 from latent image 14 shown in FIG. 2. Preferably, the parameters of the develop step are altered to reduce variation in the characteristic of patterned features 60 formed across the wafer.

In one such embodiment, control subsystem 24 is coupled to develop module 62. Wafer 12 is positioned on stage 64 that is configured to support wafer 12 during the develop step. Stage 64 is coupled to shaft 66. Shaft 66 is coupled to a motor or another device (not shown) that is configured to rotate the stage. Develop module 62 also includes develop bowl 68 in which stage 64 and wafer 12 are disposed during the develop module. Once the wafer is positioned in the develop module, developer (not shown) is dispensed onto wafer 12 through conduit 70. For a period of time after the developer is dispensed onto the wafer, the position of the wafer may be stationary. After the period of time has elapsed, the motor or other device coupled to shaft 66 rotates stage 64 and thereby wafer 12 such that the developer is spun off of the wafer. Water (not shown) may then be dispensed on the wafer (e.g., through conduit 70 or another conduit (not shown)) during rotation of the wafer. Developer and water spun off of the wafer may be collected in develop bowl 68 and removed from the bowl through drains 72 formed in the bowl.

The one or more parameters of the develop step that may be altered by the control subsystem include, for example, the amount of developer dispensed on the wafer, the positions on the wafer on which the developer is dispensed, the amount of time that the developer is in contact with the wafer, the spin rate at which the developer is spun off of the wafer, the amount of water that is dispensed on the wafer, the locations on the wafer on which the water is dispensed, the spin rate at which the water is spun off of the wafer, or some combination thereof. The one or more parameters of the develop step may be determined by the control subsystem based on the characteristic of the latent image as described further above. Preferably, the parameter(s) of the develop step are altered by the control subsystem to reduce variation in dimensions of the patterned features across the wafer.

In another embodiment, control subsystem 24 is configured to alter a parameter such as a temperature to which different portions of the wafer are exposed during a bake step performed during the lithography process after the PEB step. For example, control subsystem 24 shown in FIG. 1 may be configured to alter a parameter of a bake step performed during the lithography process after the PEB step. In this manner, the control subsystem may be configured to alter one or more parameters of the additional bake step using a feedforward control technique.

A bake step that is performed after a develop step is commonly referred to as a “hard” bake step. Such an additional bake step may be performed to remove any water remaining on the wafer after the develop step, to remove any remaining solvent from the resist patterned features, or to “harden” the patterned features in preparation for additional processes performed on the wafer such as etch and scanning electron microscopy (SEM).

In one such embodiment, control subsystem 24 is coupled to bake module 74. Bake module 74 includes bake plate 76 on which wafer 12 is disposed during the bake step performed by bake module 74. As shown in FIG. 1, the bake plate may include resistive heating element 78. Although the heating element of bake plate 76 is shown in FIG. 1 as a resistive heating element, the bake plate may include any suitable heating element known in the art. In addition, bake plate 76 may be further configured as described herein. For example, bake plate 76 may be configured as shown in FIG. 6. As described above, the parameters of the bake step performed by bake module 74 that may be altered by the control subsystem include the temperature to which different portions of the wafer are exposed during the bake step. In this manner, the temperature to which different portions of the wafer are exposed during the additional bake step may be altered and controlled independently. The temperature of the different portions may be altered as described further above. The one or more parameters of the bake step may be determined by the control subsystem based on the characteristic of the latent image as described further above. Preferably, the parameter(s) of the additional bake step are altered by the control subsystem to reduce variation in dimensions of the patterned features across the wafer.

In another embodiment, bake module 74 may also or alternatively include one or more light sources (not shown) that are configured to illuminate the wafer and thereby heat the patterned features formed on the wafer. More than one light source may be used to heat the patterned features such that individual light sources can illuminate different portions of the wafer and can be independently controlled to heat the different portions of the wafer to different temperatures. The light source(s) may include any appropriate light sources known in the art that can be used to illuminate the wafer with any suitable wavelength or wavelengths of light. In this manner, the control subsystem may be coupled to the bake module such that the control subsystem can alter one or more parameters of the individual light sources to thereby alter a temperature to which different portions of the wafer are exposed during the additional bake step. The one or more parameters of the bake step may be determined by the control subsystem based on the characteristic of the latent image as described further above. Preferably, the parameter(s) of the additional bake step are altered by the control subsystem to reduce variation in dimensions of the patterned features across the wafer.

The information collected about the latent image formed in a resist at more than one location across a wafer can, therefore, be used to modify the PEB step x-wafer using dynamic fast responding elements that are able to change temperature locally and quickly (old methods only allowed modification of bake time that affects the whole wafer), feedforward to an additional bake process that uses heating elements and/or optically based heating to allow for x-wafer latent image modification, feedforward to a develop module to modify the x-wafer signature or lithographic pattern dimensions, or some combination thereof.

Although incorporating device 10 into PEB module 18 is advantageous for reasons described above, it is to be understood that device 10 may be arranged in other positions within the lithography tool and/or additional devices may be arranged in other positions within the lithography tool. For instance, in one embodiment (not shown), the device may be arranged external to the PEB module such that the characteristic of the latent image can be measured by the device before the wafer is moved into the PEB module, as the wafer is being moved into the PEB module, as the wafer is removed from the PEB module, or after the wafer is removed from the PEB module. In one such embodiment, the device may be coupled to a wafer handler (not shown) of the lithography tool. In another such embodiment, the device may be incorporated into a cooling module (not shown) configured to reduce the temperature of the wafer subsequent to the PEB step. In this manner, the device may be configured to measure characteristic(s) of the latent image subsequent to the PEB step and during the cooling step.

In another embodiment, as shown in FIG. 1, additional device 80 may be arranged in interface 82 of the lithography tool. Interface 82 may be configured to couple the lithography track (not shown) to the exposure tool (not shown). Therefore, wafers may be moved through interface 82 from the lithography track to the exposure tool and vice versa. In addition, wafers may be positioned in the interface for a period of time (e.g., before exposure and/or after exposure). In this manner, the period of time during which the wafers are “waiting” in the interface may be advantageously used to perform the measurements described herein.

In one such embodiment, interface 82 includes wafer handler 84 on which wafer 12 and other wafers may be moved from the lithography track to the exposure tool and vice verse. Wafer handler 84 may be attached to shaft 86. Shaft 86 may be coupled to a mechanical or robotic assembly (not shown) that is configured to translate and rotate wafer handler 84. Wafer handler 84 may include any suitable wafer handler known in the art. Wafer handler 84 may also be configured to hold wafers while they are waiting to be transferred to the lithography track or the exposure tool. In one such embodiment, additional device 80 may be configured to measure a characteristic of a latent image formed in a resist at more than one location across a wafer after the exposure step and while wafer 12 is disposed on wafer handler 84. Additional device 80 may be configured as described herein. In addition, device 10 and additional device 80 may be configured similarly or differently.

Control subsystem 24 may be coupled to additional device 80 as shown by the dashed line in FIG. 1. Control subsystem 24 may be further coupled to additional device 80 as described herein. Control subsystem 24 may be configured to alter one or more parameters of the lithography process based on the characteristic of the latent image measured by additional device 80. For example, control subsystem 24 may be configured to alter one or more parameters of PEB module 18 based on the characteristic of the latent image measured by the additional device. In this manner, the control subsystem may be configured to control the PEB step by feedforward control. Preferably, one or more parameters of the PEB step are altered by the control subsystem to reduce variation in the dimensions of patterned features formed on the wafer. The parameters fed forward to the PEB module may be determined and altered by the control subsystem as described further herein.

In an additional embodiment, as shown in FIG. 1, additional device 88 may be disposed within develop module 62. In this manner, additional device 88 may be configured to measure a characteristic of a latent image formed in a resist before the develop step while wafer 12 is disposed within develop module 62. In another embodiment, additional device 88 may be configured to measure a characteristic of patterned features formed on the wafer after the develop step while the wafer is disposed within develop module 62. Additional device 88 may be configured according to any of the embodiments described herein. In addition, device 10 and additional device 88 may be configured similarly or differently. Furthermore, if additional devices 80 and 88 are coupled to the lithography tool, additional devices 80 and 88 may be configured similarly or differently.

Control subsystem 24 may be coupled to additional device 88 as shown by the dashed line in FIG. 1. Control subsystem 24 may be further coupled to additional device 88 as described herein. Control subsystem 24 may be configured to alter one or more parameters of the lithography process based on the characteristic of the latent image or patterned features measured by additional device 88. For example, control subsystem 24 may be configured to alter one or more parameters of bake module 74 based on a characteristic of the latent image or the patterned features measured by the additional device. In this manner, the control subsystem may be configured to control the bake step by feedforward control. Preferably, one or more parameters of the bake step are altered by the control subsystem to reduce variation in the dimensions of patterned features formed on the wafer. The parameters fed forward to the additional bake module may be determined and altered by the control subsystem as described further herein.

In a further embodiment, as shown in FIG. 1, additional device 90 may be disposed within bake module 74. In this manner, additional device 90 may be configured to measure a characteristic of the patterned features formed on the wafer before, during, and/or after the bake step while wafer 12 is disposed within bake module 74. Additional device 90 may be configured according to any of the embodiments described herein. In addition, device 10 and additional device 90 may be configured similarly or differently. Furthermore, if additional devices 80, 88, and 90 are coupled to the lithography tool, some, all, or none of the additional devices may be configured similarly or differently.

Control subsystem 24 may be coupled to additional device 90 as shown by the dashed line in FIG. 1. Control subsystem 24 may be further coupled to additional device 90 as described herein. Control subsystem 24 may be configured to alter one or more parameters of the lithography process based on the characteristic of the patterned features measured by additional device 90. For example, control subsystem 24 may be configured to alter one or more parameters of bake module 74 based on a characteristic of the patterned features measured by the additional device. In this manner, the control subsystem may be configured to control the bake step by in situ and/or feedback control. Preferably, one or more parameters of the bake step are altered by the control subsystem to reduce variation in the dimensions of patterned features formed on additional wafers. The parameters of the additional bake module may be determined and altered by the control subsystem as described further herein.

In another example, control subsystem 24 may be configured to alter or determine one or more parameters of a different process such as etch to be performed on the wafer based on a characteristic of the patterned features measured by additional device 90. In this manner, the control subsystem may be configured to control an etch process based on the determined parameters or to send the determined parameters to an etch module (not shown) such that the etch module can use the determined parameters of the etch process for etching of wafer 12. In this manner, the control subsystem may be configured to control the etch process by feedforward control. Preferably, one or more parameters of the etch process are altered by the control subsystem to reduce variation in the dimensions of etched patterned features (not shown) formed on the wafer. The parameters of the etch module may be determined and altered as described further herein.

Another embodiment relates to a method for controlling variation in dimensions of patterned features across a wafer. The method includes measuring a characteristic of a latent image formed in a resist at more than one location across a wafer during a lithography process. Measuring the characteristic may be performed as described herein. The method also includes altering a parameter of the lithography process in response to the characteristic to reduce variation in dimensions of patterned features formed across the wafer by the lithography process. Altering the parameter compensates for non-time varying spatial variation in a temperature to which the wafer is exposed during a PEB step of the lithography process and an additional variation in the PEB step. Altering the parameter may be performed as described further herein.

In one embodiment, the additional variation includes time varying spatial variation in the temperature. In another embodiment, the additional variation includes variation in energy transfer to the wafer. In a further embodiment, the additional variation includes variation in time between an exposure step of the lithography process and initiation of the PEB step.

In an embodiment, the parameter includes the temperature to which different portions of the wafer are exposed during the PEB step. In another embodiment, the parameter includes a temperature to which different portions of the wafer are exposed during a bake step performed during the lithography process after the PEB step. In an additional embodiment, the parameter includes a parameter of a develop step performed during the lithography process after the PEB step.

In some embodiments, measuring the characteristic includes optically measuring the characteristic of the latent image. In another embodiment, measuring the characteristic includes optically measuring the characteristic of the latent image at more than one wavelength. In an additional embodiment, measuring the characteristic includes optically measuring the characteristic of the latent image across a spectrum of wavelengths. In a further embodiment, measuring the characteristic includes optically forming an image of the latent image and determining the characteristic from the image. In a different embodiment, measuring the characteristic includes measuring byproducts of the PEB step and determining the characteristic from the byproducts.

In some embodiments, measuring the characteristic includes measuring the characteristic of the latent image at the more than one location sequentially. In a different embodiment, measuring the characteristic includes measuring the characteristic of the latent image at the more than one location simultaneously. In a further embodiment, measuring the characteristic includes measuring the characteristic of the latent image during the PEB step.

Each of the steps of the method described above may be performed as described further herein. In addition, each of the embodiments of the method described above may include any other step(s) described herein. Furthermore, each of the embodiments of the method described above may be performed by any of the system embodiments described herein. Each of the embodiments of the method described above has all of the advantages of the system embodiments described herein.

The method embodiments described above may also include any other step(s) of the methods disclosed in U.S. Pat. No. 6,689,519 to Brown et al., which is incorporated by reference as if fully set forth herein. The systems described herein may be further configured as described in this patent. In addition, the systems described herein may be further configured as described in U.S. Pat. No. 6,483,580 to Xu et al. and U.S. Pat. No. 6,590,656 to Xu et al., which are incorporated by reference as if fully set forth herein. The method embodiments described above may also include any other step(s) described in these patents.

Further modifications and alternative embodiments of various aspects of the invention may be apparent to those skilled in the art in view of this description. For example, methods and systems for controlling variation in dimensions of patterned features across a wafer are provided. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A method for controlling variation in dimensions of patterned features across a wafer, comprising:
measuring a characteristic of a latent image formed in a resist at more than one location across a wafer during a lithography process; and
altering a parameter of the lithography process in response to the characteristic to reduce variation in dimensions of patterned features formed across the wafer by the lithography process, wherein said altering compensates for non-time varying spatial variation in a temperature to which the wafer is exposed during a post exposure bake step of the lithography process and an additional variation in the post exposure bake step.

2. The method of claim 1, wherein the additional variation comprises time varying spatial variation in the temperature.

3. The method of claim 1, wherein the additional variation comprises variation in energy transfer to the wafer.

4. The method of claim 1, wherein the additional variation comprises variation in time between an exposure step of the lithography process and initiation of the post exposure bake step.

5. The method of claim 1, wherein the parameter comprises the temperature to which different portions of the wafer are exposed during the post exposure bake step.

6. The method of claim 1, wherein the parameter comprises a temperature to which different portions of the wafer are exposed during a bake step performed during the lithography process after the post exposure bake step.

7. The method of claim 1, wherein the parameter comprises a parameter of a develop step performed during the lithography process after the post exposure bake step.

8. The method of claim 1, wherein said measuring comprises optically measuring the characteristic of the latent image.

9. The method of claim 1, wherein said measuring comprises optically measuring the characteristic of the latent image at more than one wavelength.

10. The method of claim 1, wherein said measuring comprises optically measuring the characteristic of the latent image across a spectrum of wavelengths.

11. The method of claim 1, wherein said measuring comprises optically forming an image of the latent image and determining the characteristic from the image.

12. The method of claim 1, wherein said measuring comprises measuring byproducts of the post exposure bake step and determining the characteristic from the byproducts.

13. The method of claim 1, wherein said measuring comprises measuring the characteristic of the latent image at the more than one location sequentially.

14. The method of claim 1, wherein said measuring comprises measuring the characteristic of the latent image at the more than one location simultaneously.

15. The method of claim 1, wherein said measuring comprises measuring the characteristic of the latent image during the post exposure bake step.

16. A system configured to control variation in dimensions of patterned features across a wafer, comprising:
a device configured to measure a characteristic of a latent image formed in a resist at more than one location across a wafer during a lithography process; and
a control subsystem configured to alter a parameter of the lithography process in response to the characteristic to reduce variation in dimensions of patterned features formed across the wafer by the lithography process, wherein altering the parameter compensates for non-time varying spatial variation in a temperature to which the wafer is exposed during a post exposure bake step of the lithography process and an additional variation in the post exposure bake step.

17. The system of claim 16, wherein the additional variation comprises time varying spatial variation in the temperature.

18. The system of claim 16, wherein the additional variation comprises variation in energy transfer to the wafer.

19. The system of claim 16, wherein the additional variation comprises variation in time between an exposure step of the lithography process and initiation of the post exposure bake step.

20. The system of claim 16, wherein the parameter comprises the temperature to which different portions of the wafer are exposed during the post exposure bake step.

21. The system of claim 16, wherein the parameter comprises a temperature to which different portions of the wafer are exposed during a bake step performed during the lithography process after the post exposure bake step.

22. The system of claim 16, wherein the parameter comprises a parameter of a develop step performed during the lithography process after the post exposure bake step.

23. The system of claim 16, wherein the device comprises an optical device.

24. The system of claim 16, wherein the device is further configured to measure the characteristic of the latent image at more than one wavelength.

25. The system of claim 16, wherein the device is further configured to measure the characteristic of the latent image across a spectrum of wavelengths.

26. The system of claim 16, wherein the device is further configured to optically form an image of the latent image and to determine the characteristic from the image.

27. The system of claim 16, wherein the device is further configured to measure byproducts of the post exposure bake step and to determine the characteristic of the latent image from the byproducts.

28. The system of claim 16, wherein the device is further configured to measure the characteristic of the latent image at the more than one location sequentially.

29. The system of claim 16, wherein the device is further configured to measure the characteristic of the latent image at the more than one location simultaneously.

30. The system of claim 16, wherein the device is further configured to measure the characteristic of the latent image during the post exposure bake step.
